(19) United States
(12) Patent Application Publication
(10) Pub. No.: US 2025/0176369 A1
(43) Pub. Date: May 29, 2025

(54) DISPLAY PANEL AND MANUFACTURING METHOD THEREOF

(71) Applicant: HKC CORPORATION LIMITED, SHENZHEN (CN)

(72) Inventors: Yangling TANG, SHENZHEN (CN); Qin LIANG, SHENZHEN (CN); Zhisheng XIE, SHENZHEN (CN); Zhi YANG, SHENZHEN (CN); Xiufeng ZHOU, SHENZHEN (CN); Junfeng XIE, SHENZHEN (CN)

(73) Assignee: HKC CORPORATION LIMITED, SHENZHEN (CN)

(21) Appl. No.: 18/950,220

(22) Filed: Nov. 18, 2024

(30) Foreign Application Priority Data
Nov. 24, 2023 (CN) 202311583620.8

(51) Int. Cl. H10K 59/122; H10K 59/12; H10K 59/80

(52) U.S. Cl. CPC H10K 59/122; H10K 59/1201; H10K 59/80515

(57) ABSTRACT

A display panel, comprising a plurality of pixel units arranged in an array, wherein, each of the plurality of pixel units comprises a plurality of sub-pixels and a partition structure disposed between every two adjacent sub-pixels of the plurality of sub-pixels; a recess is defined in the pixel unit, a width of the recess is greater than a width of the partition structure.

### CROSS REFERENCE TO RELATED APPLICATIONS

The present application claims the priority of the Chinese patent application No. 202311583620.8, filed on Nov. 24, 2023, and contents of which are incorporated herein by its entireties.

### TECHNICAL FIELD

The present disclosure relates to the field of displaying, and in particular to a display panel and a method of manufacturing a display panel.

### BACKGROUND

An overhang (OH) structure (partition structure) in the art is usually disposed above a pixel defining layer (PDL), serving as the overhang structure.

In a manufacturing process, the PDL is made of organic material. Since the PDL made of the organic material is relatively thick, an anode aperture may be fully filled. When a surface of the filled anode aperture is flattened, the OH structure can be disposed above the anode aperture.

However, considering that a photolithography process is to be performed in a subsequent OLED process, the organic material of the PDL is less reliable. Therefore, the material of the PDL needs to be changed, and the PDL may be made of inorganic material. When the inorganic PDL is configured, the anode aperture covered by the PDL cannot be filled to be flat, resulting in the OH structure disposed at the anode aperture may be located at a slope of the aperture. In this way, a left side and a right side of the OH structure may have different angles, such that an upwardly protrusion residue may be formed, and therefore, the subsequent process may be performed abnormally, and performance of the device may be reduced.

### SUMMARY OF THE DISCLOSURE

The present disclosure provides a display panel and a method of manufacturing a display panel, in which a position of the partition structure is limited, a pixel aperture ratio is increased, and a service life of the display panel is extended.

In a first aspect, the present disclosure provides a display panel, including a plurality of pixel units arranged in an array, wherein, each of the plurality of pixel units comprises a plurality of sub-pixels and a partition structure disposed between every two adjacent sub-pixels of the plurality of sub-pixels; a recess is defined in the pixel unit, a width of the recess is greater than a width of the partition structure.

In a second aspect, the present disclosure provides a method of manufacturing a display panel, the method includes: providing a substrate; wherein a metal wire is arranged on a surface of the substrate; providing a planarization layer on the surface of the substrate and defining a recess in the planarization layer to expose the metal wire; providing a pixel anode on the surface of the planarization layer, a portion of the pixel anode extending into the recess; providing a pixel defining layer between two adjacent pixel anodes and on a surface of the pixel anode received in the recess; providing a partition structure on a surface of the pixel defining layer received in the recess, an edge of the partition structure received in the recess being un-overlapping with the side wall of the recess.

According to the present disclosure, the corresponding anode aperture is widened to form the recess, two edges of the partition structure can be received in the recess. In this way, the edges of the partition structure are prevented from overlapping with the side wall of the recess in the vertical direction, stability of the partition structure is improved. In addition, the partition structure is disposed above the non-displaying region of the pixel anode, the area of the displaying region of the pixel anode is not occupied. Compared to the technical solution of shrinking the pixel anode internally, in the present disclosure, the recess of the pixel anode is prevented from overlapping with the partition structure, such that the pixel aperture ratio is increased.

### BRIEF DESCRIPTION OF THE DRAWINGS

In order to more clearly illustrate the technical solutions in the embodiments of the present disclosure, the accompanying drawings to be used for describing the embodiments will be briefly introduced. Obviously, the following described accompanying drawings show only some of the embodiments of the present disclosure. Any ordinary skilled person in the art may obtain the other drawings based on the following drawings without making creative work.

FIG. 1 is a structural schematic view of a pixel unit of a display panel according to an embodiment of the present disclosure.

FIG. 2 is a cross-sectional view of a portion of the pixel unit shown in FIG. 1.

FIG. 3 is a structural schematic view of a partition structure according to an embodiment of the present disclosure.

FIG. 4a shows a defect of the partition structure in the art.

FIG. 4b shows another defect of the partition structure in the art.

FIG. 5 is a structural schematic view of the display panel according to an embodiment of the present disclosure.

FIG. 6 is a flow chart of a method of manufacturing the display panel according to an embodiment of the present disclosure.

10 pixel unit; 11 sub-pixel; 111 pixel anode; 1111 extension portion; 1112 display portion; 12 partition structure; 121 first partition structure; 122 second partition structure; 1211 first partition layer; 1212 second partition layer; 110 substrate; 113 planarization layer; 114 pixel defining layer; 101 recess.

### DETAILED DESCRIPTION

Technical solutions in the embodiments of the present disclosure will be described clearly and completely by referring to the accompanying drawings in the embodiments of the present disclosure. Obviously, the described embodiments are a part of, but not all of, the embodiments of the present disclosure. All other embodiments, which are obtained by any ordinary skilled person in the art based on the embodiments in the present disclosure without making creative work, shall fall within the scope of the present disclosure.

Terms used in the embodiments of the present disclosure are used merely for the purpose of describing a particular embodiment and is not intended to limit the present disclosure. The singular forms of “a”, “said”, and “the” used in the present embodiments and appended claims are intended to encompass a plurality of the structures, unless clearly indicated above. Unless other meanings are clearly indicated above, “a plurality” generally means at least two, but does not preclude the inclusion of at least one.

It should be understood that the term “and/or” as used herein is merely a description of the association relationship of associated objects, indicating that three kinds of relationships may exist. For example, A and/or B means that: A is present alone, both A and B are present, and B is present alone. In addition, the character “/” herein generally indicates that one object “or” another object. The terms “first”, “second”, and so on, in the specification, claims, and drawings of the present disclosure are used to distinguish similar objects, and shall not be interpreted as describing a particular order or sequence.

It should be understood that the terms “include,” “comprise,” and any variations thereof are intended to express non-exclusive inclusion. Therefore, a process, a method, an article, or an apparatus that comprises a set of elements includes not only the listed elements but also other elements that are not explicitly listed or that are inherently included in the process, the method, the article, or the apparatus. Without further limitation, an element that is defined by the phrase “include . . . ” does not preclude existence of additional identical elements in the process, the method, the article, or the apparatus.

It should be noted that if the embodiments of the present disclosure include directional indications (such as up, down, left, right, front, rear . . . ), the directional indications are only used to explain a relative positional relationship and movement between components in a particular attitude (the attitude as shown in the drawings). When the particular attitude is changed, the directional indications may be changed accordingly.

Reference to “embodiments” herein implies that particular features, structures, or properties described in an embodiment may be included in at least one embodiment of the present application. The presence of the term at various sections in the specification does not necessarily refer to a same embodiment, nor a separate or an alternative embodiment that is mutually exclusive of other embodiments. It is understood by any ordinary skilled person in the art, both explicitly and implicitly, that the embodiments described herein may be combined with other embodiments.

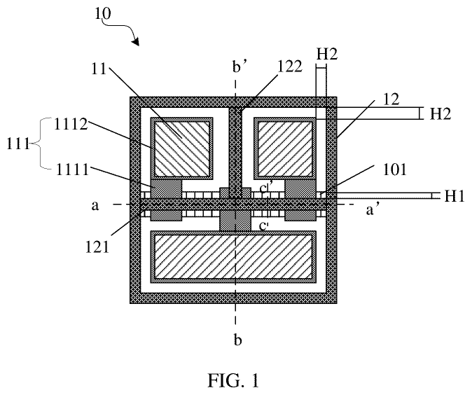

The present disclosure provides a display panel, the display panel includes a plurality of pixel units 10. As shown in FIG. 1, FIG. 1 is a structural schematic view of the pixel unit of the display panel according to an embodiment of the present disclosure. As shown in FIG. 1, each pixel unit 10 includes a plurality of sub-pixels 11 and a partition structure 12 disposed between two adjacent sub-pixels 11 of the plurality of sub-pixels 11.

The sub-pixels 11 include blue sub-pixels, green sub-pixels, red sub-pixels, and so on. In other embodiments, the sub-pixels 11 further include white sub-pixels, which are not limited herein.

The partition structure 12 is disposed around each sub-pixel 11 to enable the sub-pixel 11 to be spaced apart from any sub-pixel 11 that is surrounding the instant sub-pixel 11. Specifically, the partition structure 12 is disposed around each pixel unit 10 and is disposed between every two adjacent sub-pixels 11 within each pixel unit 10.

In the present embodiment, a recess 101 having a width greater than a width of the partition structure 12 is defined in the pixel unit 10, enabling the partition structure 12 arranged in the pixel unit 10 to be received in the recess 101. In this way, an edge of the partition structure 12 is prevented from overlapping with a side wall of the recess 101 in a direction perpendicular to a plane. Therefore, the edge of the partition structure 12 is prevented from being uneven, such that performance of the display panel may not be affected.

The number of recesses 101 may be one, and the one recess 101 extends across a pixel anode 111 of the sub-pixel 11. Specifically, the recess 101 is located corresponding to a position of an anode aperture of the pixel anode 111 of the sub-pixel 11, such that the pixel anode 111 of the sub-pixel 11 is connected, through the recess 101, to an exposed metal wire received in the recess 101, such that a signal can be transmitted to the pixel anode 111. The metal wire may be a data line. In the present embodiment, the position of the original anode aperture is widened to enable the partition structure 12 to be received in the anode aperture, preventing the edge of the partition structure 12 from overlapping with the side wall of the recess, and therefore, the partition structure 12 is formed stably.

In an embodiment, the partition structure 12 includes a first partition structure 121 received in the recess 101. A distance between an edge of the first partition structure 121 and the side wall of the recess 101 is not less than 0.2 um, as shown in FIG. 1, the distance H1≥0.2 um. In this way, the edge of the first partition structure 121 is prevented from overlapping with a slope of the side wall of the recess 101 in a vertical direction, such that formation of the first partition structure 121 is not affected.

In an embodiment, the partition structure 12 further includes a second partition structure 122 disposed on a planarized region outside the recess 101 and extending away from the recess 101. To be noted that any region outside the recess 101 is the planarized region. As shown in FIG. 1, the second partition structure 122 is located between two adjacent sub-pixels and away from the recess 101 and is located around the pixel unit 10. The second partition structure 122 is connected to the first partition structure 121. Specifically, the first partition structure 121 is connected to the second partition structure 122 on the slope of the side wall of the recess 101. In an embodiment, the first partition structure 121 and the second partition structure 122 are integrally molded as a one-piece structure on the slope of the side wall of the recess 101.

Each sub-pixel 11 includes the pixel anode 111. The pixel anode 111 of each sub-pixel 11 includes a display portion 1112 and an extension portion 1111. The extension portion 1111 of each pixel anode 111 extends into the recess 101 to be electrically connected with the exposed metal wire received in the recess 101.

In an embodiment, a distance between the second partition structure 122 disposed in the planarized region and the pixel anode 111 disposed in the planarized region is not less than 0.5 um, as shown in FIG. 1, the distance H2≥0.5 um. In this way, the second partition structure 122 and the pixel anode 111 are prevented from overlapping with each other in the vertical direction, such that during processing, no angle difference is generated between the left side and the right side of the partition structure. Specifically, the distance between the second partition structure 122 and the display portion 1112 of the pixel anode 111 is not less than 0.5 um.

In an embodiment, extension portions 1111 of pixel anodes 111 of the plurality of sub-pixels 11 of the same pixel unit 10 are disposed along a same straight line, such that the recess 101 is a straight-linear recess, and the first partition structure 121 may be easily formed inside the recess 101. In other embodiments, the extension portions 1111 of the pixel anodes 111 of the plurality of sub- pixels 11 are not disposed along the same straight line, such that the recess 101 is a curved recess, and the first partition structure 121 formed in the recess 101 is also curved. In this case, a distance between a curved position of the first partition structure 121 and the corresponding side wall of the recess 101 may not be controlled easily, difficulty of the manufacturing is improved.

In an embodiment, extension portions 1111 of pixel anodes 111 of a plurality of sub-pixels 11 of a plurality of pixel units 10 located on a same row are located along a same straight line. Detailed arrangement is not limited herein.

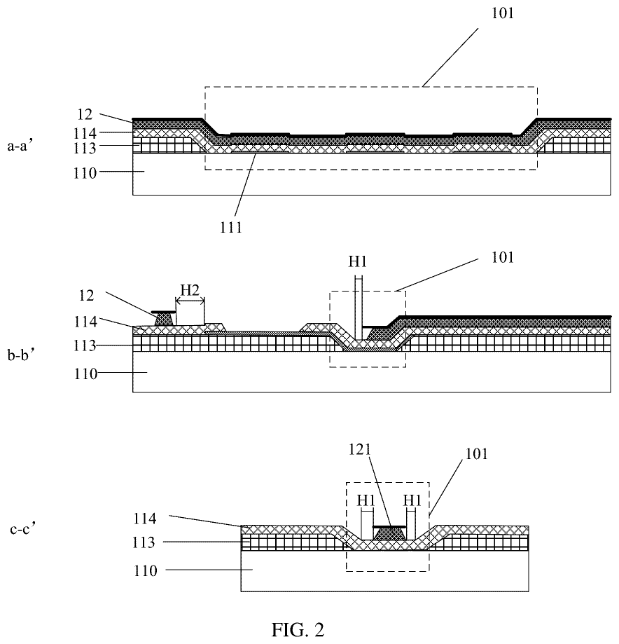

Specifically, as shown in FIG. 2, FIG. 2 is a cross-sectional view of a portion of the pixel unit shown in FIG. 1, specifically, cross-sectional views of the portion of the pixel unit of FIG. 1, taken along a line a-a′, a line b-b′, and a line c-c′, are shown. As shown in FIG. 2, the display panel includes a substrate 110, a planarization layer 113, the pixel anode 111, a pixel defining layer 114, and the partition structure 12, which are arranged sequentially.

The substrate 110 is arranged with a metal wire (not shown in the drawings). Specifically, the substrate 110 may further include a thin-film transistor layer. The metal wire includes a drain wire of the thin-film transistor, being connected with the pixel anode 111 to transmit a pixel signal to the sub-pixel 11.

The planarization layer 113 is disposed on a surface of the substrate 110 and defines the recess 101 having the width greater than the width of the partition structure 12. A portion of the metal wire is exposed from the recess 101, enabling the pixel anode 111 to be electrically connected to the metal wire received in the recess 101.

The pixel anode 111 includes the display portion 1112 arranged on a surface of the planarization layer 113 away from the substrate and the extension portion 1111 extending into the recess 101. The extension portion 1111 is electrically connected to the metal wire received in the recess 101. The display portion 1112 is configured to form a display anode of the sub-pixel 11 for displaying.

The pixel defining layer 114 is disposed between two adjacent pixel anodes 111 and covers a portion of a surface of the pixel anode 111. Specifically, pixel defining layer 114 covers a surface of the extension portion 1111 of the pixel anode 111, and the display portion 1112 is exposed, facilitating a light-emitting region of the sub-pixel to be formed.

The partition structure 12 is partially arranged on a surface of the pixel defining layer 114 away from the substrate 110. The partition structure 12 includes the first partition structure 121 received in the recess 101 and the second partition structure 122 disposed on the planarization region away from the recess 101. To be noted that a surface of the planarization layer 113 is the planarization region, and a region that defines the recess 101 is a recess region.

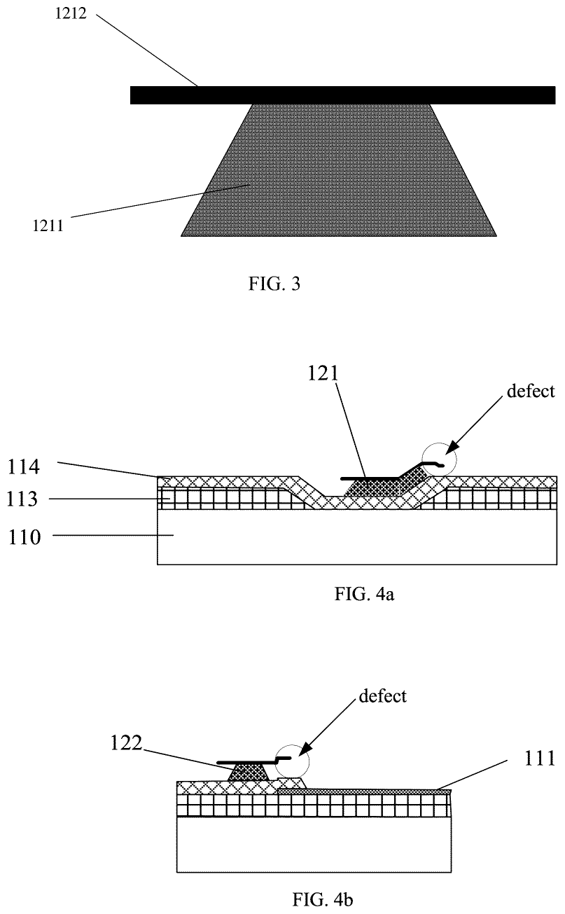

In an embodiment, the distance between the edge of the first partition structure 121 received in the recess 101 and the side wall of the recess 101 is not less than 0.2 um. As shown in FIG. 3, the distance between at least one side edge of the first partition structure 121 and the side wall of the recess 101 is not less than 0.2 um. In this way, the slope of the side wall of the recess 101 is prevented from affecting formation of a second partition layer of the first partition structure 121.

In the present embodiment, the pixel defining layer 114 is made of the inorganic material. Compared to the pixel defining layer 114 made of the organic material in the art, the pixel defining layer 114 made of the inorganic material has a reduced thickness, and the recess 101 cannot be filled to have a surface flushing with the planarization region. Therefore, the slope is formed on the side wall of the recess 101, and the slope may affect formation of the edge of the partition structure 12.

In the present embodiment, the partition structure 12 includes a first partition layer 1211 and a second partition layer 1212. As shown in FIG. 3, FIG. 3 is a structural schematic view of the partition structure according to an embodiment of the present disclosure. As shown in FIG. 3, the second partition layer 1212 is provided on a surface of the first partition layer 1211 away from the pixel defining layer 114, and a length of the second partition layer 1212 is greater than a length of the first partition layer 1211. Therefore, an eave structure is formed, facilitating the display region of the sub-pixel to be manufactured subsequently.

To be noted that an uneven surface substantially affects manufacturing of the second partition layer 1212 of the partition structure 12. As shown in FIG. 4a, when either edge of the first partition structure 121 in the recess 101 is arranged on the slope of the recess, the left side and the right side of the partition structure 12 may have different exposure angles, such that the second partition layer may have a protrusion, and therefore, a defect is caused. As shown in FIG. 4b, when the distance between the second partition structure 122 located in the planarization region and the pixel anode 111 in the display region is excessively small, the second partition layer 1212 of the partition structure 12 overlaps with the pixel anode 111 in the vertical direction, also resulting in the difference in the exposure angles of two sides of the partition structure 12, and therefore, a defect is caused.

In the present disclosure, the position of the anode aperture is widened to form the recess, the two edges of the partition structure are received in the recess, the edges of the partition structure are prevented from overlapping with the side wall of the recess in the vertical direction, such that stability of the partition structure is improved. In addition, the partition structure is disposed in the recess (that is, the extension portion) of the pixel anode, the area of the display portion of the pixel anode is not occupied. Compared to the technical solution of shrinking the pixel anode inwardly, in the present disclosure, the recess of the pixel anode is prevented from overlapping with the partition structure, such that the pixel aperture ratio is increased.

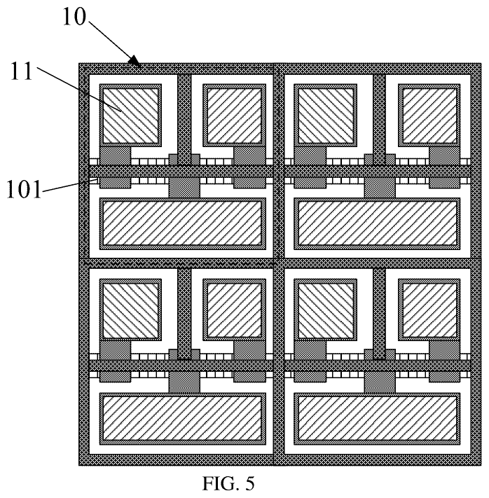

The present disclosure further provides a display panel, as shown in FIG. 5, FIG. 5 is a structural schematic view of the display panel according to an embodiment of the present disclosure. As shown in FIG. 5, the display panel includes a plurality of pixel units 10 arranged in an array. Each pixel unit 10 includes the structure as described in any of the above embodiments, which will not be limited herein. Every two adjacent pixel units 10 of the plurality of pixel units 10 are spaced apart from each other by the partition structure. That is, the two adjacent pixel units 10 share a portion of the partition structure.

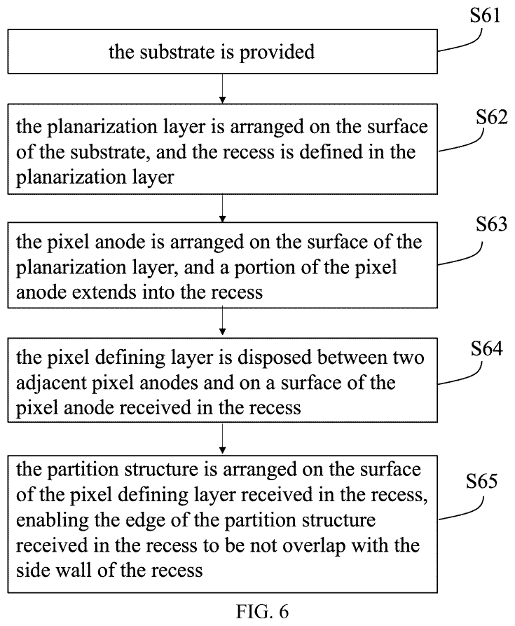

The present disclosure further provides a method of manufacturing the display panel, as shown in FIG. 6, FIG. 6 is a flow chart of the method of manufacturing the display panel according to an embodiment of the present disclosure. As shown in FIG. 6, the method includes following operations. In an operation S61, the substrate is provided.

The substrate includes the thin film transistor layer. The metal wire is arranged on a surface of the substrate, and the metal wire includes the data line and a drain metal of the thin film transistor.

In an operation S62, the planarization layer is arranged on the surface of the substrate, and the recess is defined in the planarization layer.

The metal wire is exposed from the recess. The width of the recess is greater than the width of the partition structure received in the recess.

In an operation S63, the pixel anode is arranged on the surface of the planarization layer, and a portion of the pixel anode extends into the recess.

The recess serves as an anode aperture to enable the pixel anode to be electrically connected with metal wires arranged in other layers.

The pixel anode includes the display portion and the extension portion. The display portion is configured to emit light. The extension portion is configured to be connected to the metal wire to transmit electrical signals to the pixel anode.

In an operation S64, the pixel defining layer is disposed between two adjacent pixel anodes and on a surface of the pixel anode received in the recess.

Specifically, the pixel defining layer is arranged on a surface of the pixel anode away from the substrate, covers a portion of the pixel anode, and exposes the display portion of the pixel anode, such that a pixel defining region is formed, facilitating the light-emitting region of the sub-pixel to be formed.

In an operation S65, the partition structure is arranged on the surface of the pixel defining layer received in the recess, enabling the edge of the partition structure received in the recess to be not overlap with the side wall of the recess.

Specifically, the first partition structure is arranged in the recess, and the second partition structure is arranged in a region away from the recess. The first partition structure and the second partition structure are connected to each other to form the partition structure surrounding each sub-pixel to space each sub-pixel from other sub-pixels adjacent thereto. Edges of two sides of the first partition structure are connected to the second partition structure at the slope of the recess, and edges of the other two sides are received in the recess and are away from the side wall of the recess. In this way, all edges of the partition structure do not overlap with the side wall of the recess.

According to the present disclosure, the corresponding anode aperture is widened to form the recess, two edges of the partition structure can be received in the recess. In this way, the edges of the partition structure are prevented from overlapping with the side wall of the recess in the vertical direction, stability of the partition structure is improved. In addition, the partition structure is received in the recess (extension portion) of the anode, the area of the displaying region of the pixel anode is not occupied. Compared to the technical solution of shrinking the pixel anode internally, in the present disclosure, the recess of the pixel anode is prevented from overlapping with the partition structure, such that the pixel aperture ratio is increased.

The above describes only examples of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be included in the scope of the present disclosure.

What is claimed is:

1. A display panel, comprising a plurality of pixel units arranged in an array, wherein, each of the plurality of pixel units comprises a plurality of sub-pixels and a partition structure disposed between every two adjacent sub-pixels of the plurality of sub-pixels; a recess is defined in the pixel unit, a width of the recess is greater than a width of the partition structure.

2. The display panel according to claim 1, wherein, the partition structure comprises a first partition structure received in the recess, a distance between an edge of the first partition structure received in the recess and a side wall of the recess is not less than 0.2 um.

3. The display panel according to claim 2, wherein, the partition structure further comprises a second partition structure arranged in a planarization region away from the recess, the second partition structure is connected to the first partition structure.

4. The display panel according to claim 3, wherein, the side wall of the recess has a slope, the second partition structure and the first partition structure are connected to each other at the slope.

5. The display panel according to claim 4, wherein, the second partition structure and the first partition structure are configured as a one-piece structure at the slope of the side wall of the recess.

6. The display panel according to claim 3, wherein, any region located out of the recess is the planarization region.

7. The display panel according to claim 3, wherein, each of the plurality of sub-pixels comprises a pixel anode, the pixel anode comprises a display portion and an extension portion, the extension portion of the pixel anode extends into the recess to be electrically connected with an exposed metal wire received in the recess.

8. The display panel according to claim 7, wherein, the recess is located corresponding to a position of an anode aperture of the pixel anode.

9. The display panel according to claim 7, wherein a distance between the second partition structure arranged in the planarization region and the display portion of the pixel anode arranged in the planarization region is not less than 0.5 um.

10. The display panel according to claim 7, wherein, extension portions of pixel anodes of the plurality of sub-pixels of a same one of the plurality of pixel units are located along a same straight line.

11. The display panel according to claim 10, wherein, the recess is a straight-linear recess.

12. The display panel according to claim 7, wherein, extension portions of pixel anodes of the plurality of sub-pixels of a same one of the plurality of pixel units are not located along a same straight line.

13. The display panel according to claim 12, wherein, the recess is curved.

14. The display panel according to claim 1, further comprising:
a substrate, wherein a metal wire is arranged on a surface of the substrate;
a planarization layer, covering the surface of the substrate and defining the recess, which has the width greater than the width of the partition structure, wherein a portion of the metal wire is exposed from the recess;
a pixel anode, comprising: a display portion arranged on a surface of the planarization layer away from the substrate; and an extension portion extending into the recess, wherein the extension portion is electrically connected to the metal wire received in the recess;
a pixel defining layer, disposed between two adjacent pixel anodes and covering a surface of the extension portion of the pixel anode.

15. The display panel according to claim 14, wherein, the partition structure is arranged on a surface of the pixel defining layer away from the substrate.

16. The display panel according to claim 14, wherein, the pixel defining layer is made of inorganic material.

17. The display panel according to claim 14, wherein, the partition structure comprises a first partition layer and a second partition layer, the second partition layer is arranged on a surface of the first partition layer away from the pixel defining layer;
in a direction parallel to the substrate, a length of the second partition layer is greater than a length of the first partition layer.

18. A method of manufacturing a display panel, the method comprising:
providing a substrate; wherein a metal wire is arranged on a surface of the substrate;
providing a planarization layer on the surface of the substrate and defining a recess in the planarization layer to expose the metal wire;
providing a pixel anode on the surface of the planarization layer, a portion of the pixel anode extending into the recess;
providing a pixel defining layer between two adjacent pixel anodes and on a surface of the pixel anode received in the recess;
providing a partition structure on a surface of the pixel defining layer received in the recess, an edge of the partition structure received in the recess being un-overlapping with the side wall of the recess.

19. The method according to claim 18, wherein, the partition structure comprises a first partition structure received in the recess, a distance between an edge of the first partition structure received in the recess and a side wall of the recess is not less than 0.2 um.

20. The method according to claim 19, wherein, the partition structure further comprises a second partition structure arranged in a planarization region away from the recess, the second partition structure is connected to the first partition structure.
